(19) United States
(12) Patent Application Publication
(10) Pub. No.: US 2008/0196229 A1
(43) Pub. Date: Aug. 21, 2008

(54) Tool For Stretching the Foil of a Foil Carrier, a Machine For Removing Dies From a Wafer and a Method For Removing Dies

(75) Inventor: Gerardus Wilhelmus Van Beuningen, Beuningen (NL)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: NXP B.V., Eindhoven (NL)

(21) Appl. No.: 11/917,100

(22) PCT Filed: Jun. 9, 2006
(86) PCT No.: PCT/IB06/51846

§ 371 Date: Dec. 10, 2007

(30) Foreign Application Priority Data
Jun. 16, 2005 (EP) 05105326.2

(51) Int. Cl. H01L 21/78; B26F 3/02

(52) U.S. Cl. 29/239; 225/93; 225/103; 225/105

(57) ABSTRACT

The present invention relates to a tool for stretching the foil (2) of a foil carrier (1), the foil being connected to a frame (3), which tool comprises a circular inner body (6) and a circular outer body (7), the foil being stretched by supporting the frame with at least one body and moving one body with respect to the other body in axial direction, the inner body extending in the outer body, wherein coupling means (10) are provided, which couples during a rotational movement from one body in relation to the other, and which converts this rotational movement into the required axial movement stretching the foil (2). The invention furthermore also relates to a machine and a method for removing dies from a foil carrier.

The present invention relates to a tool for stretching the foil of a foil carrier, the foil being connected to a frame, which tool comprises an inner body and an outer body having an opening, the foil being stretched by supporting the frame with at least one body and moving one body with respect to the other body in axial direction, the inner body extending in the opening of the outer body.

The present invention also relates to a machine for removing dies from a wafer that is disposed on a foil carrier, the machine comprising a tool for stretching a foil carrier.

Furthermore the present invention relates to a method for removing dies from a wafer.

A tool as described in the first paragraph is for example described in U.S. Pat. No. 5,979,728, which discloses an apparatus for breaking and separating dies from a wafer. Such an application is also the basis for the present invention, although the tool can be used for any foil disposed on a frame that needs to be stretched. The bodies in the U.S. patent comprise an anvil and a base fixture respectively. The foil is placed between an inner and an outer ring that together form a frame. When the anvil is moved in axial direction with respect to base fixture the inner ring of the frame moves axially with respect to the outer ring resulting in stretching of the flexible foil.

A problem of this known tool is that the tool for stretching the foil occupies a lot of space. This is mainly relevant regarding the axial dimensions thereof (axial with respect to the circular bodies). The anvil requires some kind of driving means to bring about the axial movement. In U.S. Pat. No. 5,979,728 it suggested to use some sort of driving shaft or rod for this. Regarding its function this shaft will extend substantially in the axial direction.

Usually the tool is applied in combination with other tools, which are required to process the dies after they are separated by stretching the foil. For example one can think of testing tools or a pick and place tool that removes the individual dies from the foil and put them in an external package or on a substrate. Giving the orientation of the dies on the wafer the other tools will also mainly extend in the axial direction. Since the tools stretching the foil are by definition situated on the backside of the foil, i.e. the backside of the wafer, these other tools most likely will extend in a direction opposite to the stretching tool. This results in an even larger occupation of the space regarding the axial direction.

It is an object of the present invention to provide a tool according to the first paragraph that requires less space in an axial direction.

The present invention provides a tool for stretching a foil carrier according to claim 1. Instead of imposing an axial movement only, a rotational movement or torque is imposed on at least one of the bodies, which movement is converted by means of the coupling means to the required axial movement. In this way a lever action is obtained, which will be explained in more detail below. Especially when the bodies have relatively large outer dimensions a strong lever action can be obtained. Therefore the driving means that drive the required movement of the bodies and that can be any kind of motor or actuator, such as an electromotor, can have a compact and lightweight design. Since no direct axial drive of one of the bodies is required the driving means will occupy less space in this direction. The coupling means even make it possible to impose the necessary rotational movement manually. This can be facilitated for example by mounting a handle to the outer body. The most common example of coupling means that have a similar function as the coupling means according to the invention is the screw thread that is disposed respectively on a cap and a top of a bottle.

In a preferred embodiment according to the invention the coupling means comprise protrusions and elongated recesses, the protrusions are disposed at one body and couple with the recesses disposed at the other body, which recesses extend in both the tangential and axial direction with respect to the corresponding body. This gives a straightforward construction for the coupling means and reduces the space that is occupied in a radial direction, at least compared to the situation wherein either the protrusions or the recesses are disposed outside the outer body. It is especially preferred that the recesses have a small angle of inclination with respect to their longitudinal direction. These recesses can be designed to have such an angle of inclination that is for example smaller than 10 degrees. A small angle of inclination will give a maximal lever action. Designing the corresponding circular body with a relatively large diameter facilitates such an angle.

In another preferred embodiment an outer surface of the outer body or an inner surface of the inner body is toothed. It is especially preferred that a gear wheel is driven by an electromotor, the gear wheel coupling with the toothed surface. This results in an efficient driving mechanism to obtain the required rotational movement.

The present invention also relates to a machine for removing dies from a wafer, which is disposed on a foil carrier, the machine comprising a tool for stretching a foil carrier according to the invention, which tool is arranged on a machine support, and comprising a pick and place unit to pick the individual dies from the foil carrier and place them on an external part, the unit being arranged on the machine support and facing the tool. Preferably a testing unit is also mounted on the machine support in order to test the individual dies. This provides a machine that is capable of both testing dies on a wafer and removing the dies thereof. The machine will occupy a relatively small amount of space in the axial direction. Furthermore the machine needs a relatively low force to drive the tool for stretching the foil and is therefore relatively lightweight.

The present invention also relates to a method for removing dies from a foil carrier with a machine according to the invention, the method comprising;

providing a foil carrier, the foil supporting a wafer with a plurality of dies, the dies being separated along their edges;

placing the foil carrier between an inner and an outer body;

rotating both bodies with respect to each other in a first direction and converting the rotational movement to a relative axial movement stretching the foil;

picking the individual dies from the wafer and placing the dies in an external part;

rotating both bodies with respect to each other in a direction opposite to the first direction to release the foil;

removing the foil carrier between the inner and outer body.

This results in a rapid method to remove the dies from a wafer. Preferably the method also comprises a step in which the dies are tested on their functioning.

It is especially preferred when such a method furthermore comprises;

providing a plurality of foil carriers, each foil supporting a wafer with a plurality of dies;

placing the foil carriers in a rack;

picking a foil carrier from the rack and placing the foil carrier between an inner and an outer body;

removing the foil carrier between the inner and outer body and placing the foil carrier back in the rack.

These steps allow to have an interrupted process by partly process a wafer, then temporarily store a foil carrier in the rack and finally place the foil carrier between the circular bodies at a later stage to further process the dies that are still on the wafer. Of course the steps of the above mentioned methods could be combined in any arbitrary and advantageous sequence. Furthermore this method allows to increase the overall process speed, since a plurality of wafers can be processed successively without human intervention. This can be made possible by automating the corresponding process steps and providing for example an external package that is arranged on a reel.

The invention will be explained further below under reference to the accompanying drawings, in which:

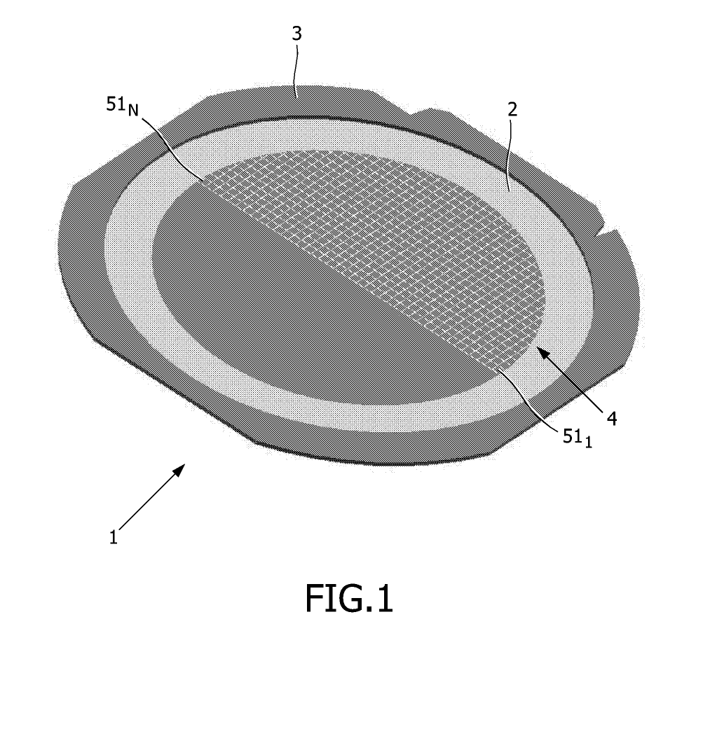

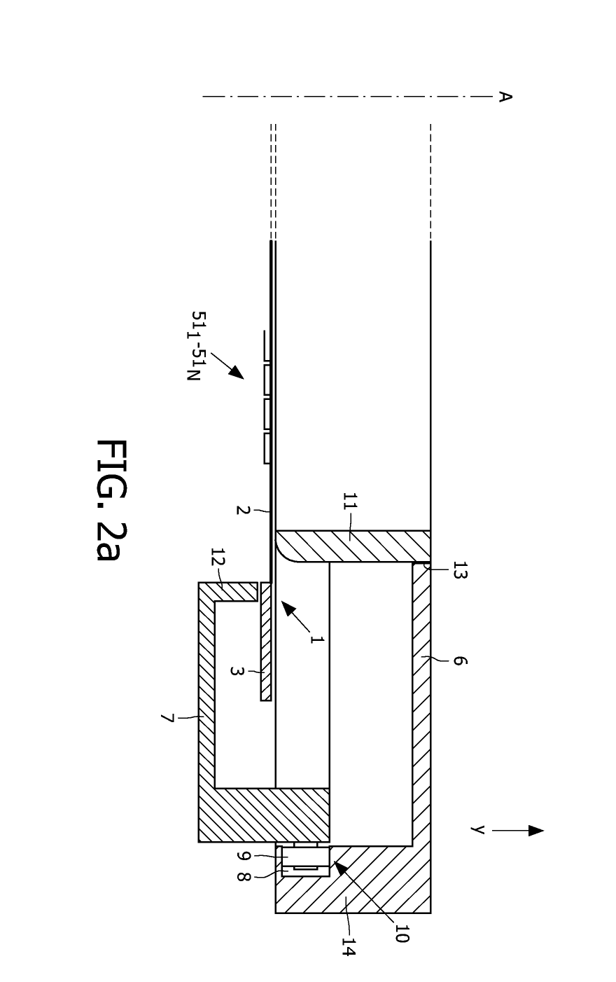

FIG. 1 is a perspective view of a foil carrier comprising a wafer

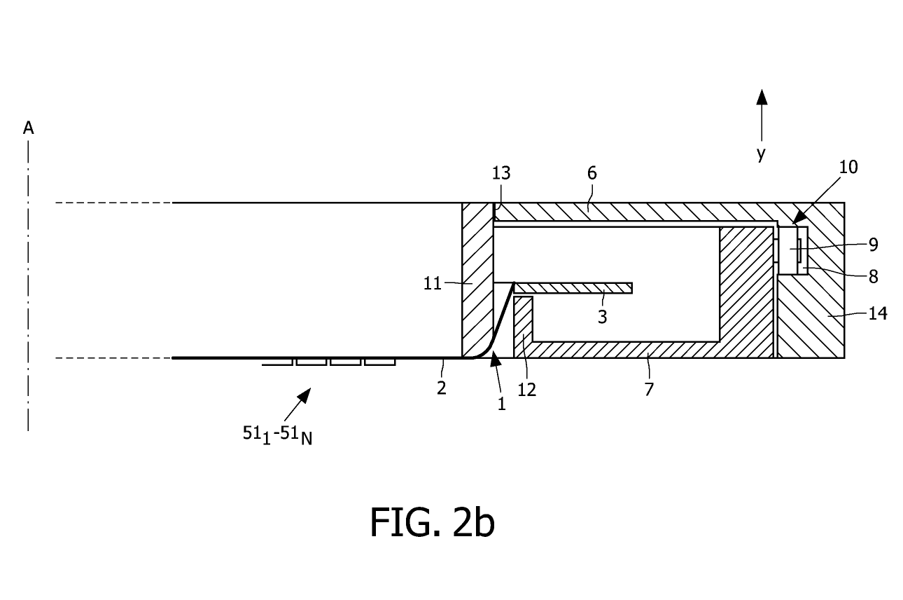

FIG. 2a is a cross-section of the tool according to a preferred embodiment, the tool holding a foil carrier in a starting position;

FIG. 2b is a cross-section of the tool according to a preferred embodiment, the tool holding a foil carrier in a stretched position;

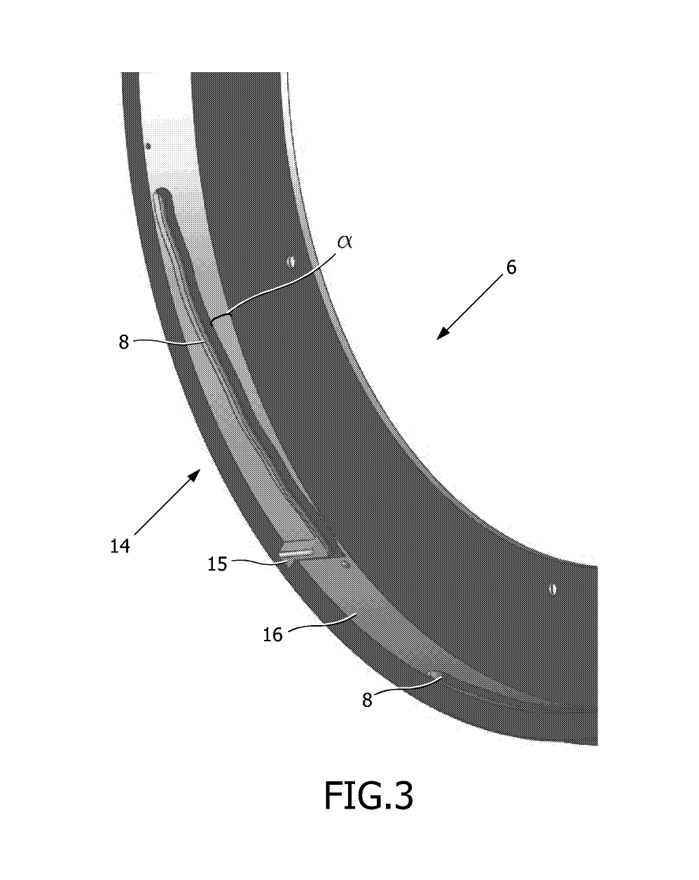

FIG. 3 is a perspective partial view of the inner body;

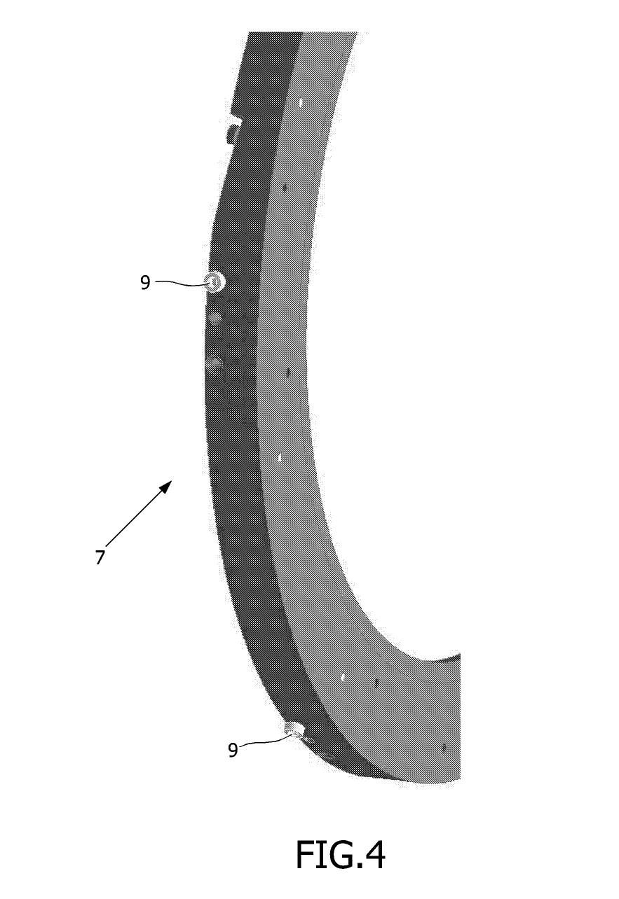

FIG. 4 is a perspective partial view of the outer body;

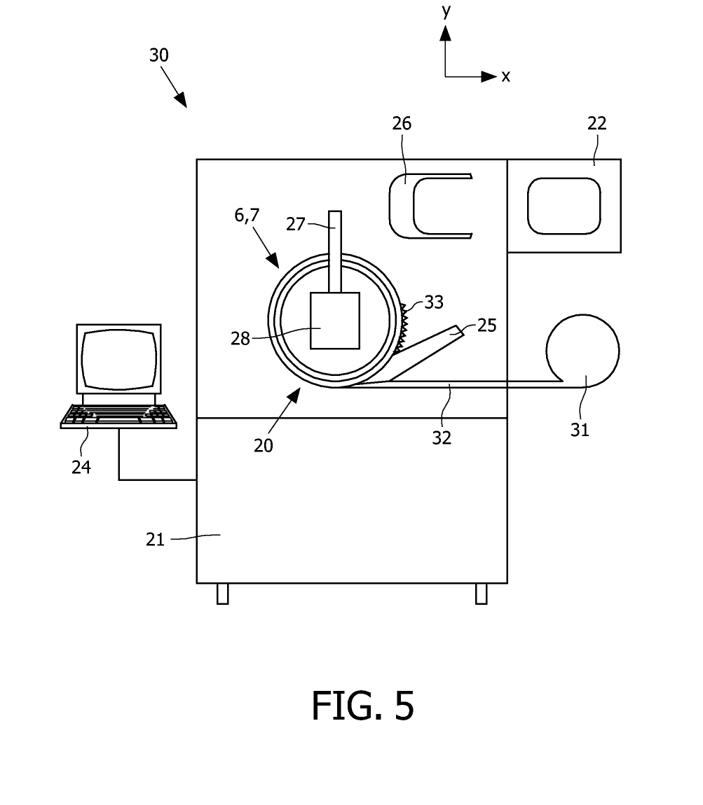

FIG. 5 is a schematic drawing of a machine for removing dies from a wafer.

FIG. 1 shows a foil carrier 1, which comprises a foil 2 that is connected to a ring shaped frame 3 along its outer edges. On the foil a wafer 4 is glued, the wafer comprising a plurality of dies 51₁-51ₙ. The dies can be end products or dies that are processed partly. With ‘dies’ it is meant any individual component of a semiconductor substrate, such as IC's, discrete transistors, MEMS-components, passive networks, etc. Although the invention primarily is focused on foil carriers comprising a wafer (sometimes referred to as film frame carrier or FFC in the art), its principle can be used on any foil that is connected to a frame and needs to be stressed reversibly.

The principle of the present invention can best be explained with FIGS. 2a and 2b, which show cross-sections of the tool according to a preferred embodiment, the tool holding a foil carrier in a starting and a stretched position respectively. Besides the foil carrier 1 these Figures show a circular inner body 6 and a circular outer body 7. Both bodies are preferably ring-shaped. The outer body 7 comprises a flange 12, which supports frame 3 of the foil carrier 1. The inner ring comprises a flange 11, which contacts the foil in operating condition. The flange 11 of the inner body is arranged at the interior of the outer body, at least in operating condition. Therefore body 6 is referred to as the inner body, despite the fact that another part 14 of this body is arranged outside the outer body 7, which may seem somewhat confusing at first sight.

Both bodies comprise coupling means 10; a recess 8 is disposed in the inner body 6, while a protrusion 9 is mounted to the outer body 7, which protrusion couples with the recess. From the starting position a rotational movement around rotation axis A is imposed on one body with respect to the other body. The protrusion 9 hereby travels trough the recess 8, which has such a course that this rotational movement is converted to or results in a simultaneous displacement in the axial direction Y of one body with respect to the other. Due to this displacement the flange 11 extends in the opening of the outer body 7 and stretches the foil 2 of the foil carrier 1. The circular flange 12 defines this opening of outer body 7. By imposing a rotational movement in the opposite direction the starting position is reached again, thereby releasing the foil. The diameter of both bodies in practice will be much larger than it is suggested in FIGS. 2a and 2b. When placed between the bodies 6,7 the dies 51₁, 51ₙ are facing the outer body 7.

Flange 11 has a flexible connection 13 with the remainder of the inner body 6. This is advantageous in order to prevent rimpling or crinkling of the foil that is located between the flanges 11 and 12.

In a special embodiment (not shown in FIGS. 2a and 2b) the inner body has a special flange 11 that is adapted to co-operate with flange 12 to just clamp the frame 3 without stretching the foil. This embodiment can for example be used when the tool is used just for testing the dies of a wafer that are disposed on a foil carrier that is clamped by the tool.

FIGS. 3 and 4 show a perspective partial view of the inner and outer body respectively. From this Figure it can clearly be seen that both bodies are ring-shaped and relatively thin, which is advantageous in keeping the total weight of the tool low. Typical thickness of the flanges 11 and 12 are 3 mm and 7 mm respectively. Typical outer diameters of both bodies 6 and 7 are 335 mm and 320 mm respectively.

It is shown also in FIGS. 3 and 4 that the each body comprises either a number of elongated recesses 8 or protrusions 9 respectively. Preferably in total 6 recesses are arranged in the inner body 6, which extend by definition over less than 60 degrees along the perimeter of an inner surface 16 a part 14. Each recess has an entrance part 15, which is meant to guide the protrusions in the recesses in the first stage. This means that the driving means are adapted to also impose an axial movement on the bodies with respect to each other, but this is a movement over a limited distance. Moreover when the projections and recesses are properly aligned such a movement will require just a very low driving force.

In order to illustrate the recesses more clearly flange 11 (see FIGS. 2a and 2b) is not displayed in FIG. 3. The recess extends both in the tangential and the axial direction with respect to the inner body 6, the tangential component being much larger than the axial component. Therefore the angle of inclination α of the recess is relatively small, preferably smaller than 10 degrees. A typical example is an angle of inclination of approximately 5°. This small angle of inclination allows that one can easily apply a large torque that brings about the required axial displacement Therefore the lever action as mentioned before is maximized.

FIG. 5 schematically displays a machine 30 for removing dies from a wafer. The machine comprises a machine support 21. At least the following parts are mounted to the machine support;

a tool 20 for stretching the foil of a foil carrier that is movable in the x,y-direction and that comprises two circular bodies 6,7.

a rack 22 adapted to accommodate a plurality of foil carriers;

transportation tool 26 movable in the x,y-direction as well as rotatable in the x,y-plane to transfer the foil carriers between the tool 20 and the rack 22;

a reel 31 supplying a packaging member 32;

a pick and place unit 28 to remove the dies on the foil (the dies being arranged on a wafer that is attached to the foil) and place them in the packaging member 32;

a driving means 25 to impose an axial and rotational movement on one of the bodies 6,7 with respect to the other body;

an observation assembly 27 to view the individual dies.

The machine is operated by means of a control unit 24. The driving means 25 preferably comprise an electromotor that drives a gear wheel coupled to a toothed surface 33, which is disposed along at least a part of a circular body. Its main dimension extends in the x,y-plane. It is also possible to drive the tool with a hydraulic device or to impose the required movements of the bodies manually. The driving means are adapted to impose a rotational movement on one body with respect to the other body. By means of coupling means this movement is converted into an axial movement, which stretches a foil carrier that is clamped between the bodies. By means of a reversed rotation the foil carrier is released again.

Preferably at least one of the bodies comprise an opening at its side, which opening faces the transportation tool 26 in its loading position and is meant to respectively receive and release a foil carrier when this carrier is respectively placed between the bodies or removed thereof by this transportation tool. More preferably such an opening is arranged only in the outer body.

Since the tool 20 for stretching is relatively light weight, as it is explained before, its speed in the x,y-direction with respect to the pick and place unit 28 for processing the individual dies can be relatively high. This will increase the overall output of the machine.

The pick and place unit 28 may also comprise a test tool to test the functionalities of the individual dies. Such a test tool would comprise very fine needles that contact the active areas of the die. The observation assembly 27 preferably comprises a digital camera that is connected to the control unit 24. The functional parts of the unit 28 are facing the tool 20. In order to pick up and hold a die the pick and place unit 28 usually applies vacuum.

Preferably the machine comprises some kind of blower (not shown) that is adapted to blow a flow of hot air towards the backside of the foil. This allows recovery of the foil after it has been stretched. Furthermore it is preferred that the control unit combines the rest result of the individual dies with the control of the pick and place unit 28. In this way disfunctioning dies can be separated from the rest.

The machine is well equipped for performing the method for removing dies from a foil carrier according to the present invention. Referring to FIGS. 1 and 2 it is illustrated hereunder what exactly is meant with the step ‘placing the foil carrier between the bodies’, which is one of the steps of this method. In fact FIG. 2A illustrates most clearly how the foil carrier is orientated after it has been placed between bodies 6 and 7. The flange 12 of the outer body 7 supports the frame 3. The flange 12 of the inner body 6 contacts the backside of the foil 2. The front side of the foil carries the dies 51₁-51ₙ, which face the outer body 7.

Instead of putting the individual dies in an external packaging member 32 it is also possible to place a die on substrate that is supplied to the machine. Subsequently the die is connected to the substrate by means of soldering. Preferably therefore the machine is also equipped with a soldering device or similar connection means.

During the stretching operation the foil is stretched by about 10%. This leads to an increase of the mutual distance between the individual dies, which are beforehand separated along their edges, of 10%. Preferably the dies are separated by means of a very precise sawing process. In practice this mutual distance will increase from 50 (saw width) to about 55 μm. An even more important consequence of stretching the foil is that the adherence of the individual dies to the foil is considerably reduced, which makes it much more easy to remove them from the foil.

It should be noted that the above-mentioned embodiments illustrate rather than limits the invention, and that those skilled in the art will be capable of designing many alternative embodiments without departing from the scope of the invention as defined by the appended claims. In the claims, any reference signs placed in parentheses shall not be construed as limiting the claims. The word “comprising” and “comprises”, and the like, does not exclude the presence of elements or steps other than those listed in any claim or the specification as a whole. The singular reference of an element does not exclude the plural reference of such elements and vice-versa.

1. A tool for stretching the foil of a foil carrier, the foil being connected to a frame, which tool comprises an inner body and an outer body having an opening; the foil being stretched by supporting the frame with at least one body and moving one body with respect to the other body in axial direction, the inner body extending in the opening of the outer body, characterized in that coupling means are provided, which couples during a rotational movement from one body in relation to the other, and which converts this rotational movement into the required axial movement stretching the foil.

2. A tool as claimed in claim 1, characterized in that the coupling means comprises protrusions and elongated recesses, the protrusions are disposed at one body and couple with the recesses disposed at the other body, which recesses extend in both the tangential and axial direction with respect to the corresponding body.

3. A tool as claimed in claim 2, characterized in that the recesses with respect to their longitudinal dimension have a small angle of inclination, such as smaller than 10 degrees.

4. A tool as claimed in claim 1, characterized in that an outer surface of the outer body or an inner surface of the inner body toothed.

5. A tool as claimed in claim 4, characterized in that a gear wheel is driven by an electromotor, the gear wheel coupling with the toothed surface.

6. A machine for removing dies from a wafer, the wafer being disposed on a foil carrier, the machine comprising:
a tool a tool for stretching the foil of a foil carrier, the foil being connected to a frame, which tool comprises an inner body and an outer body, having an opening; the foil being stretched by supporting the frame with at least one body and moving one body with respect to the other body in axial direction, the inner body extending in the opening of the outer body, wherein coupling means are provided, which couples during a rotational movement from one body in relation to the other, and which converts this rotational movement into the required axial movement stretching the foil;
the tool being arranged on a machine support, and comprising a pick and place unit to pick the individual dies from the foil carrier and place them on an external part of part of the pick and place unit, the pick and place unit being arranged on the machine support and facing the tool.

7. A method for removing dies from a foil carrier with a machine according to claim 6, the method comprising;
providing a foil carrier, the foil supporting a wafer with a plurality of dies, the dies being separated along their edges;
placing the foil carrier between an inner and an outer body;
rotating both bodies with respect to each other in a first direction and converting the rotational movement to a relative axial movement stretching the foil;
picking the individual dies from the wafer and placing the dies in an external part;
rotating both bodies with respect to each other in a direction opposite to the first direction to release the foil;
removing the foil carrier between the inner and outer body.

8. A method for removing dies from a foil carrier with a machine according to claim 7, characterized in that the method furthermore comprises;
providing a plurality of foil carriers, each foil supporting a wafer with a plurality of dies;
placing the foil carriers in a rack;
picking a foil carrier from the rack and placing the foil carrier between an inner and an outer body;
removing the foil carrier between the inner and outer body and placing the foil carrier back in the rack.
